(19) United States
(12) Patent Application Publication
(10) Pub. No.: US 2007/0043989 A1
(43) Pub. Date: Feb. 22, 2007

(54) Method for specifying failure position in scan chain

(76) Inventor: Junichi Yokota, Kyoto (JP)

Correspondence Address: MCDERMOTT WILL & EMERY LLP, 600 13TH STREET, N.W., WASHINGTON, DC, 20005-3096, US

(21) Appl. No.: 11/498,757

(22) Filed: Aug. 4, 2006

(30) Foreign Application Priority Data
Aug. 5, 2005 (JP) 2005-227722

(51) Int. Cl. G01R 31/28

(52) U.S. Cl. 714/726

(57) ABSTRACT

It is judged whether or not a scan chin has a failure, an arbitrary data string is inputted to the malfunction scan chain judged that a failure is present by a capture action through a combination circuit, the data string is outputted from a scan-out terminal of the malfunction scan chain to which the data string is inputted, and the failure position of the malfunction scan chain is specified based on a comparison between the outputted data string and the expected value of the data string.

### BACKGROUND OF THE INVENTION

1. Field of the Invention

The present invention relates to a method for specifying a failure position in a scan chain of a semiconductor integrated circuit.

2. Description of the Related Art

FIG. 4 shows an example of the structure diagram of a scan chain of a conventional semiconductor integrated circuit disclosed in Japanese Patent Literature (Japanese Unexamined Patent Publication H6-230075), for example. Each of scan flip-flops F1-F5 constituting a scan chain c10 comprises a set terminal and a reset terminal for enabling set/reset processing. In detection of a malfunction flip-flop, first, each of the flip-flops F1-F5 is set to have a prescribed bit value of “0” or “1” by using the set terminal or the reset terminal. Through this step, the scan chain c10 is set into a prescribed bit string. Then, scan-shift is performed within the scan chain c10 for obtaining an output bit: string by shifting it out from the scan-out terminal. Then, the output bit string is compared to an expected bit string (set bit string), and the malfunction flip-flop is specified based on the inconsistent part. If the any of the flip-flops malfunctions and it is held at “0” or “1”, the held value is to be outputted thereafter regardless of the value of the flip-flop of the preceding stage thereof. Therefore, the flip-flop corresponding to the part whose value is not consistent with the expected value in the output string is specified as the defective one.

Next, a specific example will be described. It is assumed here that there is 0-stuck-at-fault between the flip-flop F2 and the flip-flop F3 as marked with “x” in FIG. 4. “Stuck-at-fault” is a failure where the input terminal or the output terminal of the logic gate, flip-flop, and the like keeps staying at the logic value of “1” or “0”. The failure keeps staying at “0” is referred to as 0-stuck-at-fault and the failure staying at “1” as 1-stuck-at-fault. The arrangement of the bit string “11111” written here is in the same order of the illustrated flip-flops F1-F5 where the leftmost is the value of the flip-flop F1 and the rightmost is the value of the flip-flop F5. Thus, shift-in and shift-out is started in order from the right side of the bit string. The bit string of “11111” is set by using the set terminal of the malfunction scan chain c10, and it is compared to the value shifted out from the scan-out terminal. In this case, as there is 0-stuck-at-fault shown with “x” in the output side of the flip-flop F2, the value to be shifted out is “00111” regardless of the value of the flip-flop on the scan-in side from the flip-flop F2. In this shift-out value, the values of the flip-flops on the scan-in side from the flip-flop F2 are different from the expected value “11111”. Therefore, it can be specified that there is a failure between the output of the flip-flop F2 and the input of the flip-flop F3.

When the malfunction flip-flop is specified by the conventional method described above, it is necessary for all the flip-flops to have the set/reset terminals. If there is even one flip-flop that has no set/reset terminal, there is no guarantee that the flip-flop with possible malfunction can be specified to be one. In that case, it may happen that the position of the malfunction flip-flop can be specified only as a range where a plurality of flip-flops exists. This will be described below by referring to FIG. 5A and FIG. 5B.

Among flip-flops F1-F5 belonging to a scan chain c20 shown in FIG. 5A and FIG. 5B, the flip-flops F2 and F4 have the set terminal, the flip-flop F3 has the reset terminal, and the other flip-flops have neither the set terminal nor the reset terminal. In FIG. 5A, it is assumed that there is 0-stuck-at-fault marked with “x” generated between the flip-flop F2 and the flip-flop F3. In FIG. 5B, it is assumed that there is 0-stuck-at-fault marked with “x” generated between the flip-flop F3 and the flip-flop F4. The bit string of “X1X1X” is set in the scan chain c20 by using the set terminal and it is made shift-out from the scan-out terminal. Then, the set bit string is compared to the shifted out value.

In the structure shown in FIG. 5A, there is 0-stuck-at-fault on the input side of the flip-flop F3 that has no set terminal. Thus, the value shifted out from the scan-out terminal is “00X1X”, which is inconsistent with the expected value at the flip-flop F2. This indicates that there is a failure on the output side of the flip-flop F2, which is consistent with the actual failure part.

In the case of the structure shown in FIG. 5B, however, there is 0-stuck-at-fault on the output side of the flip-flop F3 that has no set terminal. Thus, the shifted out value is “0001X”. Based on this shift-out value, the flip-flop value having the inconsistency with respect to the expected value becomes the flip-flop F2 like the above-described case, so that it is misjudged that there is the failure on the output side of the flip-flop F2.

As shown in FIG. 5A and FIG. 5B, when a failure is generated in the part where the expected value thereof is an indefinite value “X” (the flip-flop having no set/reset terminals), it is not possible to judge directly whether the failure part is generated on the output side or the input side of the flip-flop. Thus, the malfunction flip-flop cannot be specified to be one.

### SUMMARY OF THE INVENTION

The main object of the present invention therefore is to provide a failure position specification method that can accurately specify the failure position in a scan chain without adding any special modification to a circuit structure.

In order to overcome the aforementioned problems, the method for specifying the failure position in a scan chain according to the present invention is a method for specifying failure position in a scan chain that comprises a plurality of flip-flops connected in parallel to be capable of transmitting data, wherein a scan-in terminal is provided to one end of row of the flip-flops and a scan-out terminal is provided to other end of the row respectively, and each of the flip-flops is connected so as to be capable of transmitting data to a combination circuit. The method comprises steps of:
a malfunction scan chain judgment step for judging whether or not there is a failure in the scan chain;
a data string input step for inputting an arbitrary data string to a malfunction scan chain judged as having a failure by a capture action through the combination circuit;
a data string output step for outputting the data string from the scan-out terminal of the malfunction scan chain to which the data string is inputted; and
a failure position specification step for specifying a failure position in the malfunction scan chain based on a comparison between the outputted data string and an expected value of the data string.

That is, an arbitrary bit string is set in the malfunction scan chain by the capture action from the combination circuit, through use of the combination circuit that is necessarily provided to the flip-flops of the scan chain; the output bit string thereof is obtained by scan-shift; and the position of the malfunction flip-flop is specified by comparing the output and the expected value. As described, an arbitrary bit string can be set in the malfunction scan chain through the combination circuit. Thus, it is possible to specify the failure position of the scan chain accurately without adding any special modification to the circuit structure even if all the flip-flops don't have the set/reset terminals.

It is preferable that the present invention further comprise a plurality of the scan chains, wherein the flip-flops constituting each of the plurality of scan chains are connected through the combination circuit so as to be capable of transmitting data with each other, wherein
the malfunction scan chain judgment step specifies a malfunction scan chain having a failure and normal scan chains having no failure from the plurality of scan chains, and
a test pattern generating step and a test pattern input step are provided further between the scan chain judging step and the data string input step, wherein:
the test pattern generation step generates a test pattern to satisfy a condition that the data string is inputted to the malfunction scan chain without changing a data structure thereof in the input step if the test pattern is inputted to the scan-in terminals of the normal scan chains even though continuous data of an undefined value “X” is inputted to the scan-in terminal of the malfunctioning chain as the test pattern inputted to the scan-in terminal of the respective normal scan chains; and
the test pattern input step inputs the generated test pattern to the scan-in terminals of the normal scan chains and the continuous data of the undefined value “X” to the scan-in terminal of the malfunction scan chain, respectively.

In order to set the arbitrary bit string to the malfunction scan chain by using the combination circuit, it is necessary to perform automatic generation of the test patterns and input the initial value to the flip-flop positioned on the preceding stage side of the combination circuit. Further, in order for the generated test pattern to be shifted in properly to the malfunction scan chain, the initial value is required to be in the pattern that can be shifted in to the malfunction scan chain. By generating the test pattern that satisfies the above-described condition at the time of generating the test pattern, the initial value (the continuous value of the undefined value “X”) can be shifted in to the malfunction scan chain accurately.

It is preferable that the present invention further comprise a plurality of the scan chains, wherein the flip-flops constituting each of the plurality of scan chains are connected through the combination circuit to be capable of transmitting data with each other, wherein
the malfunction scan chain judging step specifies a malfunction scan chain having a failure and normal scan chains having no failure from the plurality of scan chains, and further specifies a failure value in the specified malfunction scan chain, and
a test pattern generation step and a test pattern input step are provided further between the scan chain judgment step and the data string input step, wherein:
the test pattern generation step generates a test pattern to satisfy a condition that the data string is inputted to the malfunction scan chain without changing a data structure thereof in the input step if the test pattern is inputted to the scan-in terminals of the normal scan even though continuous data of the failure value is inputted to the scan-in terminal of the malfunctioning chain; and
the test pattern input step inputs the generated test pattern to the scan-in terminals of the normal scan chains and the continuous data of the failure value to the scan-in terminal of the malfunction scan chain, respectively.

According to this, variations of the generable test patterns can be increased so that the state of the malfunction scan chain after the capture action can be easily set to an arbitrary state. As a result, the failure position can be easily specified.

Further, it is preferable in the present invention that at least one of the flip-flops comprise at least either a set terminal or a reset terminal; and
the test pattern generation step generates a test pattern to satisfy such a condition that the data string is inputted to the malfunction scan chain without changing the data structure thereof by the input step if the test pattern is inputted to the scan-in terminals of the normal scan chains even though the continuous data of the undefined value “X” is inputted to the scan-in terminal of the malfunctioning chain as the test pattern and there is also input of setting to the flip-flop that comprises either the set terminal or the reset terminal performed through the set terminal or the reset terminal.

According to this, variations of the generable test patterns can be increased so that the state of the malfunction scan chain after the capture action can be easily set to an arbitrary state. As a result, the failure position can be easily specified.

Further, it is preferable in the present invention that at least one of the flip-flops comprise at least either a set terminal or a reset terminal; and
when the data string contains an undefined value “X”, the data string input step performs set processing on the flip-flop having the set terminal within the scan chain and reset processing on the flip-flop having the reset terminal respectively, after inputting the data string, in order to reset the data string to be inputted to the malfunction scan chain without changing the data structure thereof.

According to this, the data string can be reset to the arbitrary data string even if the undefined value “X” is contained in the arbitrary data string that is set to the malfunction scan chain from the combination circuit. As a result, it becomes easy to specify the malfunction position.

According to the present invention the arbitrary bit string can be set in the malfunction scan chain through the combination circuit. Therefore, it is possible to specify the failure position of the scan chain accurately without adding any special modification to the circuit structure even if all the flip-flops don't have the set/reset terminals.

The method for specifying the failure position in a scan chain according to the present invention is effective as a technique for specifying a malfunction flip-flop among a group of flip-flops on a scan chain in a semiconductor integrated circuit that comprises a scan chain.

### BRIEF DESCRIPTION OF THE DRAWINGS

Other objects of the present invention will become clear from the following description of the preferred embodiments and the appended claims. Those skilled in the art will appreciate that there are many other advantages of the present invention not mentioned in this specification by embodying the present invention.

FIG. 1 is a flowchart for showing operation of a method for specifying a failure position in a scan chain according to first to third embodiments of the present invention;

FIG. 2 is a flowchart for showing operation of a method for specifying a failure position in a scan chain according to a fourth embodiment of the present invention;

FIG. 3 is a schematic circuit diagram of a semiconductor integrated circuit for describing the method for specifying a failure position in a scan chain according to the embodiments of the present invention;

FIG. 4 is a constitutional diagram of a scan chain according to a related art;

FIG. 5A is a constitutional diagram of the scan chain according to the related art; and

FIG. 5B is a constitutional diagram of the scan chain according to the related art.

### DETAILED DESCRIPTION OF THE INVENTION

Preferred embodiments of the present invention will be described hereinafter by referring to the accompanying drawings.

(First Embodiment)

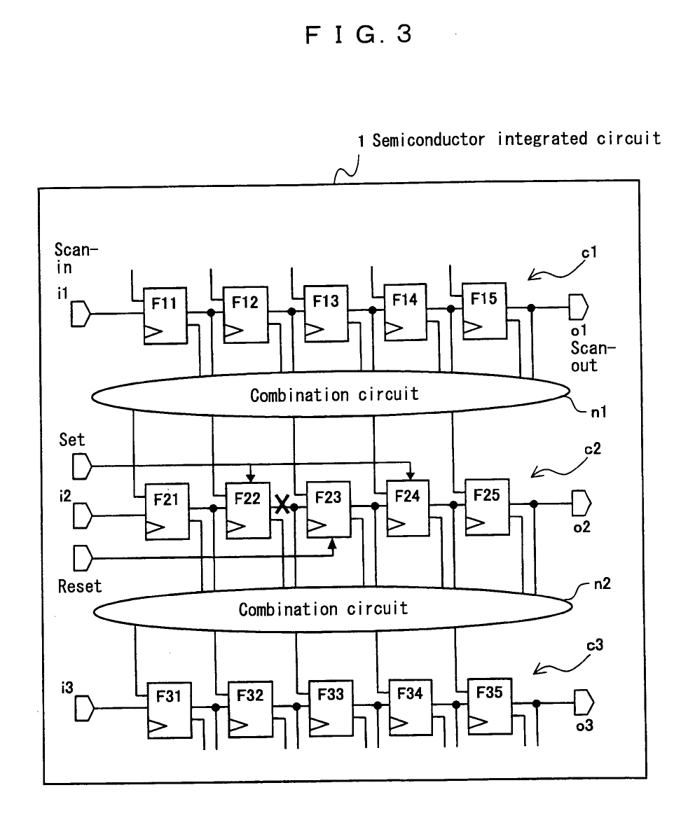

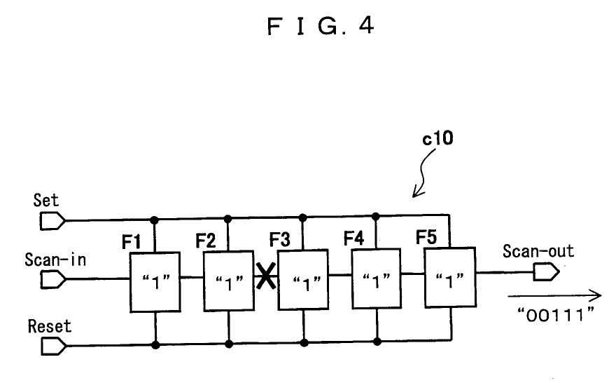

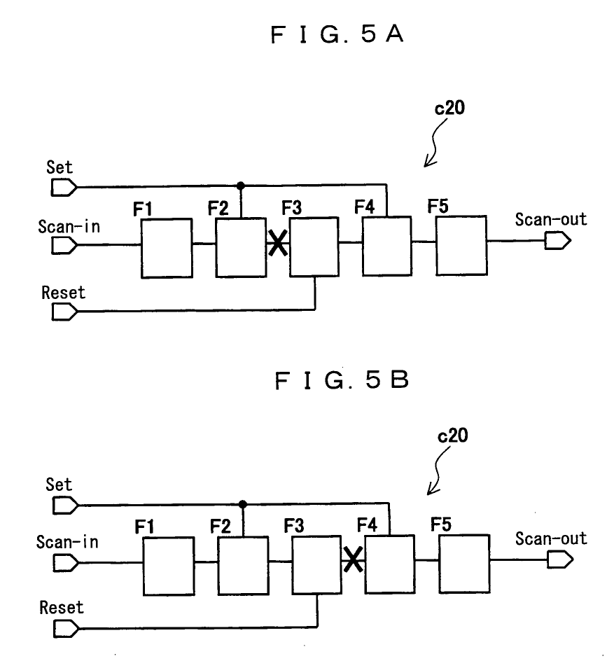

FIG. 3 is a schematic circuit diagram of a semiconductor integrated circuit for describing the method for specifying a failure position in a scan chain according to a first embodiment of the present invention. A semiconductor integrated circuit 1 shown in FIG. 3 comprises first to third scan chains c1, c2 and c3. The first scan chain c1 comprises five-stage scan flip-flops F11-F15 connected in a chain form. The second scan chain c2 comprises five-stage scan flip-flops F21-F25 connected in a chain form. The third scan chain c3 comprises five-stage scan flip-flops F31-F35 connected in a chain form.

The flip-flops F11-F15 constituting the first scan chain c1 are connected to the flip-flops F21-F25 constituting the second scan chain c2 through a first combination circuit n1. The flip-flops F21-F25 constituting the second scan chain c2 are connected to the flip-flops F31-F35 constituting the third scan chain c3 through a second combination circuit n2. Each of the flip-flops comprises an input terminal that is connected to the combination circuit n1 and n2, and an input terminal to which the scan input is inputted. Each flip-flop is controlled by a scan enable signal.

For allowing the present invention to be easily comprehended, the terminologies thereof are defined. In the method of the present invention, there are two ways of operations for inputting the bit string to the first to third scan chains c1-c3. The first operation is an input action for substituting an arbitrary value to a malfunction scan chain by a capture action through the combination circuit n1 and n2. This is defined as “to set”. The second operation is an input action for setting the arbitrary value to the malfunction chain, which is an input action for inputting a test pattern generated by a automatic test pattern generation tool (AGPT) to the flip-flops constituting the malfunction scan chain through scan-in terminals i1-i3. This is defined as “to input an initial value”. The malfunction scan chain means the scan chain having a failure. Further, among the flip-flops constituting the scan chains c1-c3, there are the one positioned on the input side (the side to input the value to the combination circuit) and the one positioned on the output side (the side where the value is outputted from the combination circuit) when it is viewed from the combination circuit n1 and n2. In the first embodiment, the flip-flops to which the initial value is inputted are the flip-flops positioned in the input side of the combination circuit n1 and n2.

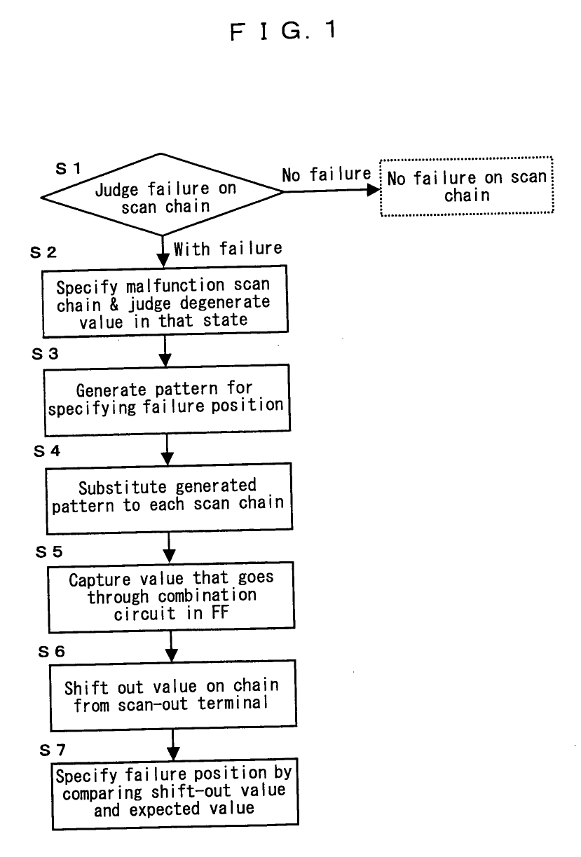

The method for specifying the failure position in a scan chain according to the first embodiment of the present invention is described by referring to the flowchart shown in FIG. 1. Here, in the scan chain c2 of FIG. 3, the case is explained as an example that there is 0-stuck-at-fault as marked with “X” generated between the second-stage flip-flop F22 from the scan-in terminal i2 and the third-stage flip-lop F23. In the following explanation, when the first to third scan chains c1-c3 are described with emphasis on whether or not they have a failure, they are referred to as the second scan chain (failure) c2, and the first, third scan chains (normal) c1 and c3.

First, in step S1 it is judged whether or not there is a failure in the first to third scan chains c1-c3. That is, arbitrary data is inputted to the flip flops of the first to third scan chains c1-c3 from the respective scan-in terminals i1-i3, which are then scan-shifted in each of the chains c1-c3 and outputted from the scan-out terminals o1-o3. Based on:this action, it is judged whether or not the data inputted to the first to third scan chains c1-c3 through the scan-in terminals i1-i3 are consistent with the data outputted from the scan-out terminals o1-o3 after shifted by five stages. Here, when it is judged to be consistent, it is determined that there is no failure in the first to third scan chains c1-c3. In the meantime, when it is judged to be inconsistent, it is determined that there is a failure.

In the case of FIG. 3, the scan-in value and the scan-out value are consistent in the first scan chain (normal) c1 and the third scan chain (normal) c3 that has been supposed to have no failure. Meanwhile, the values are not consistent in the second scan chain (failure) c2 that is supposed to have 0-stuck-at-fault. Thus, it is judged in step S1 that there is a failure in one of the first to third scan chains c1-c3.

Then, in step S2, the malfunction scan chain having a failure is specified and the kinds of the failure (0-degeneracy or 1-degeneracy) occurring in the specified malfunction scan chain is specified. The position where the failure is produced is not specified in this step.

The processing of step S2 will be described referring to a specific example. First of all, the scan-in value and the scan-out value are consistent in the first scan chain c1 and the third scan chain c3 but not consistent in the second scan chain c2. Thus, the second scan chain c2 is specified as the malfunction scan chain.

Further, when the data “11100” is shifted in from the scan-in terminal i2 in the state where there is 0-stuck-at-fault generated in the second scan chain c2, the data “00000” is shifted out from the scan-out terminal o2. When such input/output state is observed, the failure present in the second scan chain c2 is specified as 0-stuck-at-fault.

Then, a test pattern for specifying the position of the failure is automatically produced in step S3. This test pattern is generated based on condition that an arbitrary data string is properly set in the malfunction scan chain in steps S4 and S5 which will be described later. The initial values to be shifted in to the first and third scan chains (normal) c1 and c3, i.e. the test patterns are produced such that the data string to be set in the second scan chain (failure) c2 through the first combination circuit n1 by a capture action becomes a pre-designated one (for example, “11111”) even if the initial values inputted from the scan-in terminal i2 to the second scan chain (failure) c2 are all undefined values, “XXXXX”.

Next, generation of the test pattern will be described in detail. In order to set the arbitrary data string properly to the second scan chain (failure) c2 by the capture action, it is necessary to set the initial value properly not only for the first scan chain c1 but also for all the scan chins c1-c3. The reason for this is because there may be cases where the output signal of the flip-flop F22 is fed back to the flip-flop F24 through the combination circuit in the second scan chain (failure) c2, for example.

It is assumed here that the initial values for accurately setting the data string “11111” to the second scan chain c2 are “11000” (the first scan chain c1), “10111” (second scan chain c2), and “00001” (third scan chain c3) under presumption that there is supposedly no failure generated in any of the scan chains c1-c3. In this state, further, it is assumed that 0-stuck-at-fault is generated in the second scan chain c2. On this condition, the initial value “10000” is actually inputted to the second scan chain (failure) c2 even if the initial value “10111” is inputted from the scan-in terminal i2 to the second scan chain (failure) c2. Thus, the data string to be set in the second scan chain (failure) c2 by the capture action through the first combination circuit n1 is not “11111”.

Therefore, when generation of the patterns is carried out in step S3, the initial values to be shifted in to the scan chains (normal) c1 and c3 are automatically generated as the test patterns so as to satisfy such condition that the value to be set to the second scan chain (failure) c2 through the combination circuit becomes “11111” even if the initial values inputted from the scan-in terminal i2 to the second scan chain (failure) c2 are all undefined values, “XXXXX”. Thereby, the data string to be set to the second scan chain (failure) c2 through the combination circuit in step S5 to be described later can be set properly as “11111” regardless of the initial values inputted to the second scan chain (failure) c2.

Then, in step S4, the test patterns generated in step S3 are inputted to the scan chains (normal) c1 and c3, respectively, through the scan-in terminals i1 and i3, while the initial values (undefined values, “XXXXX”) are inputted to the scan chain (failure) c2 through the scan-in terminal i2.

Subsequently, in step S5, a capture action is carried out by the combination circuits n1, n2 in which the test patterns and the initial values (undefined values, “XXXXX”) inputted to the scan chains c1-c3 are used, and then the data string is set to the second scan chain (failure) c2. At this time, the data string to be set in the second scan chain (failure) c2 through the first combination circuit n1 (also the second combination circuit in some cases) becomes the desired data string “11111” despite of that the initial values inputted from the scan-in terminal i2 to the second scan chain c2 are all undefined values, “XXXXX”.

Then, in step S6, the data string set in the second scan chain (failure) c2 is scan-shifted in this scan chain, which is then outputted from the scan-out terminal o2.

In step S7, the outputted data string is compared to the expected values of the data string. The expected value here is “11111”. However, when it proceeds to step S7 in the state of the above-described failure the data string outputted from the scan-out terminal o2 becomes “00111” because there exists 0-stuck-at-fault between the flip-flop F22 and the flip-flop F23. When this is observed, it is judged that a failure is present on the output side of the flip-flop F22 based on the result of the observation.

According to the embodiment, the failure position in the scan chain can be specified accurately without applying any special modification to the circuit structure even if all the flip-flops don't have the set-reset terminals.

(Second Embodiment)

In the first embodiment, the following condition is imposed in the step (step S3) for automatically generating the test patterns to be shifted in to the scan chains c1-c3. That is, it is so imposed as a condition in the test-pattern generation step (step S3) that the values to be set in the second scan chain (failure) c2 through the combination circuit become “11111” even if the initial values to be inputted to the second scan chain (failure) c2 are the continuous values of the undefined value, “XXXXX”.

This embodiment pays attention to the fact that the failure value in the second scan chain (failure) c2 is already identified at the stage of step S2 where it is checked whether or not the scan chain has a failure. The failure value is “0” in the case of 0-stuck-at-fault and it is “1” in the case of 1-stuck-at-fault. In the case of above-described step S2, the failure value is judged as “0” in step S2.

As described, the failure value is identified in advance. Thus, instead of that the initial values that are supplied to the malfunction scan chain specified as having a failure (the second scan chain c2 in the above-described case) at the time of automatic generation of the test pattern for specifying the failure position, is set as the continuous values of the undefined value, “XXXXX”, the values “00000” or “11111” which are obtained when the identified failure value (degenerate values) are propagated to the input side, are set as the initial value. In the case of step S2 described above, “00000” is used as the initial value to be inputted to the second scan chin (failure) c2.

By increasing variations of the initial values to be inputted to the scan chin (failure) through the combination circuit in the manner described above, it is possible to generate still larger number of patterns as the automatically generated test patterns. By doing this, the failure position can be more easily specified.

(Third Embodiment)

Alike the first and second embodiments, it is set as the condition for generating the test patterns in this embodiment to input the continuous values of the undefined value, “XXXXX”, or the value (“00000” or the like) that is obtained by propagating the identified failure value (degenerate value) to the scan chain (failure), to the malfunction scan chain (the second scan chain c2).

In the embodiment, further, the following condition is added as a condition for generating such test patterns. That is, such a condition is added in this embodiment, that the initial values (“X101X” or the like) are inputted to the malfunction scan chain without a change in the data structure when the test pattern is inputted to the scan-in terminal of the normal scan chain under the state where the initial values are changed (the state where the initial values become “X101X” in the case of FIG. 3) by inputting the setting to the set terminals and the reset terminals of the flip-flops (flip-flops F21-F25) belonging to the malfunction scan chain (the second scan chain c2).

This allows an increase in variations of the initial values inputted to the malfunction scan chain through the combination circuit, so that still larger number of patterns can be generated as the automatically generated test patterns. Therefore, the failure position can be specified still more easily.

(Fourth Embodiment)

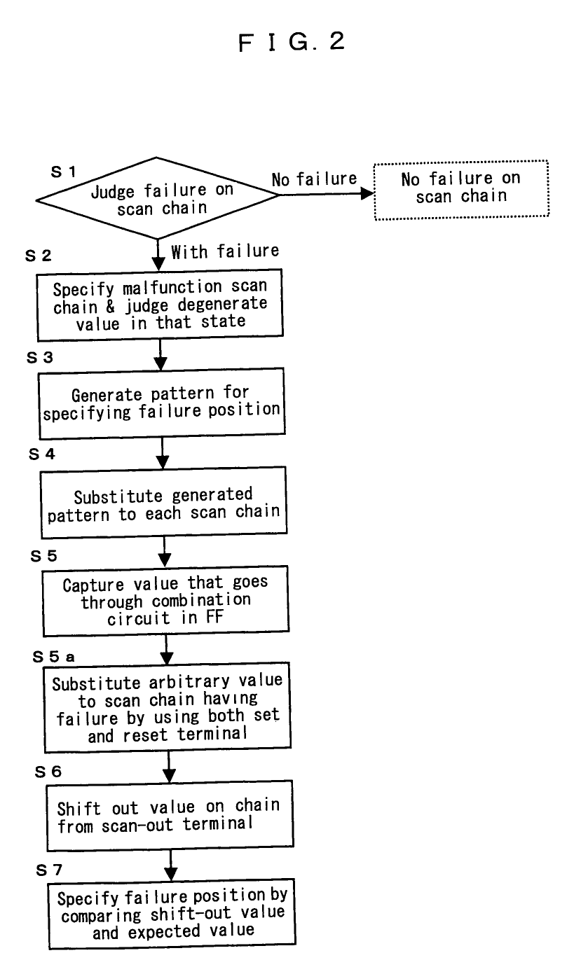

The method for specifying the failure position in a scan chain according to a fourth embodiment of the present invention will be described referring to the flowchart shown in FIG. 2. This embodiment is different from the fist embodiment at a point that an additional step S5a is added between step S5 and step S6. In step S5, the capture action is carried out to set arbitrary values to the second scan chain (failure) c2 using the values to be inputted to the scan chains c1-c3. When the initial values to be inputted to the second scan chain (failure) c2 are changed at this time from the originally inputted data string to the data string of “1X1X1” despite of that the capture action is carried out by using the test patterns generated by the test-pattern automatic generating action, set processing and reset processing to the second scan chain (failure) c2. is performed in step S5a through the set/reset terminals provided to the flip-flops F21-F25 that belong to the second scan chain (failure) c2 to reset the initial values to be inputted. Thereby, the initial values to be inputted finally to the second scan chain (failure) c2 are corrected to the originally inputted data string (“11111” or the like). By allowing the initial values to be inputted to the second scan chain (failure) c2 to be alterable even after the capture action, it becomes possible to increase the variations. Thus, the failure position can be specified still more easily.

The aforementioned first to fourth embodiments have been described referring to the case of specifying the failure position on an assumption that there is 0-stuck-at-fault. However, the present invention can also specify the failure position in the case of 1-stuck-at-fault. Furthermore, the failure position can be specified accurately even anywhere the failure is in the scan chain.

The present invention has been described in detail with respect to the most preferred embodiments. However, various combinations and modifications of the components are possible without departing from the sprit and the broad scope of the appended claims.

What is claimed is:

1. A method for specifying failure position in a scan chain that comprises a plurality of flip-flops connected in parallel so as to be capable of transmitting data, wherein a scan-in terminal is provided to one end of row of said flip-flops and a scan-out terminal is provided to other end of said row, respectively, and each of said flip-flops is connected to a combination circuit so as to be capable of transmitting data, said method comprising steps of:
a malfunction scan chain judgment step for judging whether or not there is a failure in said scan chain;
a data string input step for inputting an arbitrary data string to a malfunction scan chain judged that a failure is present by a capture action through said combination circuit;
a data string output step for outputting said data string from said scan-out terminal of said malfunction scan chain to which said data string is inputted; and
a failure position specifying step for specifying a failure position in said malfunction scan chain based on a comparison between outputted said data string and an expected value of said data string.

2. The method for specifying failure position in a scan chain according to claim 1, comprising a plurality of said scan chains, wherein said flip-flops constituting one of said plurality of scan chains and said flip-flops constituting another one of said scan chains are connected through said combination circuit so as to be capable of transmitting data with each other, wherein
said malfunction scan chain judgment step specifies a malfunction scan chain having a failure and normal scan chains having no failure from said plurality of scan chains, and
a test pattern generation step and a test pattern input step are provided further between said scan chain judgment step and said data string input step, wherein:
said test pattern generation step generates a test pattern, as a test pattern inputted to each of said scan-in terminal of said normal scan chains, that satisfies such a condition that said data string is inputted to said malfunction scan chain without changing a data structure in said input step through input of said test pattern to said scan-in terminals of said normal scan chains even though continuous data of an undefined value “X” is inputted to said scan-in terminal of said malfunction scan chain; and
said test pattern input step inputs generated said test pattern to said scan-in terminals of said normal scan chains and said continuous data of said undefined value “X” to said scan-in terminal of said malfunction scan chain, respectively.

3. The method for specifying failure position in a scan chain according to claim 1, comprising a plurality of said scan chains, wherein said flip-flops constituting one of said plurality of scan chains and said flip-flops constituting another one of said scan chains are connected through said combination circuit to be capable of transmitting data with each other, wherein
said malfunction scan chain judgment step specifies a malfunction scan chain having a failure and normal scan chains having no failure from said plurality of scan chains, and further specifies a failure value in specified said malfunction scan chain and
a test pattern generation step and a test pattern input step are provided further between said scan chain judgment step and said data string input step, wherein:
said test pattern generation step generates a test pattern, as a test pattern inputted to each said scan-in terminal of said normal scan chains, that satisfies such a condition that said data string is inputted to said malfunction scan chain without changing a data structure thereof in said input step through input of said test pattern to said scan-in terminals of said normal scan chains even though continuous data of said failure value is inputted to said scan-in terminal of said malfunction scan chain; and
said test pattern input step inputs generated said test pattern to said scan-in terminals of said normal scan chains and said continuous data of said failure value to said scan-in terminal of said malfunction scan chain, respectively.

4. The method for specifying failure position in a scan chain according to claim 2, wherein:
at least one of said flip-flops comprises at least either a set terminal or a reset terminal; and
said test pattern generation step generates a test pattern, as said test pattern, that satisfies such a condition that said data string is inputted to said malfunction scan chain without changing said data structure in said input step through input of said test pattern to said scan-in terminals of said normal scan chains even though said continuous data of said undefined value “X” is inputted to said scan-in terminal of said malfunction scan chain and input of setting is also performed to said flip-flop that comprises either said set terminal or said reset terminal through said set terminal or said reset terminal.

5. The method for specifying failure position in a scan chain according to claim 3, wherein:
at least one of said flip-flops comprises at least either a set terminal or a reset terminal; and
said test pattern generation step generates a test pattern, as said test pattern, that satisfies such a condition that said data string is inputted to said malfunction scan chain without changing said data structure in said input step through input of said test pattern to said scan-in terminals of said normal scan chains even though continuous data of said failure value is inputted to said scan-in terminal of said malfunctioning chain and input of setting is also performed to said flip-flop that comprises either said set terminal or said reset terminal through said set terminal or said reset terminal.

6. The method for specifying failure position in a scan chain according to claim 2, wherein:
at least one of said flip-flops comprises at least either a set terminal or a reset terminal; and
when said data string contains said undefined value “X”, said data string input step performs set processing to said flip-flop having said set terminal within said scan chain and reset processing to said flip-flop having said reset terminal, respectively, in order to reset so that said data string is inputted to said malfunction scan chain without changing said data structure thereof.

7. The method for specifying failure position in a scan chain according to claim 3, wherein:
at least one of said flip-flops comprises at least either a set terminal or a reset terminal; and
when said data string contains an undefined value “X”, said data string input step performs set processing to said flip-flop having said set terminal within said scan chain and reset processing to said flip-flop having said reset terminal, respectively, in order to reset so that said data string is inputted to said malfunction scan chain without changing said data structure.
